(19) United States
(12) Patent Application Publication
(10) Pub. No.: US 2009/0293952 A1
(43) Pub. Date: Dec. 3, 2009

(54) Thin Film Photovoltaic Module

(76) Inventors: Francois Andre Koran, Longmeadow, MA (US); Jun Lu, East Longmeadow, MA (US); Steven Vincent Haldeman, Hampden, MA (US)

Correspondence Address: HAMILTON, BROOK, SMITH & REYNOLDS, P.C., 530 VIRGINIA ROAD, P.O. BOX 9133, CONCORD, MA, 01742-9133, US

(21) Appl. No.: 12/472,444

(22) Filed: May 27, 2009

Related U.S. Application Data
(60) Provisional application No. 61/056,260, filed on May 27, 2008.

(51) Int. Cl. H01L 31/00; H01L 31/18

(52) U.S. Cl. 136/256; 438/64; 257/E21.499

(57) ABSTRACT

The present invention provides a thin film photovoltaic device comprising a poly(vinyl butyral) layer that provides excellent adhesion, resistivity, sealing, processability, and durability to the device.

### CROSS-REFERENCE TO RELATED APPLICATIONS

This application claims priority to U.S. Provisional Application 61/056,260, filed on May 27, 2008, which is hereby incorporated by reference in its entirety.

### FIELD OF THE INVENTION

The present invention is in the field of thin film photovoltaic modules, and, specifically, the present invention is in the field of thin film photovoltaic modules incorporating a polymer layer and a photovoltaic device on a suitable thin film photovoltaic substrate.

### BACKGROUND

There are two common types of photovoltaic (solar) modules in use today. The first type of photovoltaic module utilizes a semiconductor wafer as a substrate and the second type of photovoltaic module utilizes a thin film of semiconductor that is deposited on a suitable substrate.

Semiconductor wafer type photovoltaic modules typically comprise the crystalline silicon wafers that are commonly used in various solid state electronic devices, such as computer memory chips and computer processors. This conventional design, while useful, is relatively expensive to fabricate and difficult to employ in non-standard applications.

Thin film photovoltaics, on the other hand, can incorporate one or more conventional semiconductors, such as amorphous silicon, on a suitable substrate. Unlike wafer applications, in which a wafer is cut from an ingot in a complex and delicate fabrication technique, thin film photovoltaics are formed using comparatively simple deposition techniques such as sputter coating, physical vapor deposition (PVD), or chemical vapor deposition (CVD).

While thin film photovoltaics are becoming more viable as a practical photovoltaic option to wafer photovoltaics, improvement in the efficiency, durability, and manufacturing expense are needed in the art.

### SUMMARY OF THE INVENTION

The present invention provides a thin film photovoltaic device comprising a poly(vinyl butyral) layer that provides excellent adhesion, resistivity, sealing, processability, and durability to the device.

### BRIEF DESCRIPTION OF THE DRAWINGS

FIG. 1 represents a schematic cross sectional view of a thin film photovoltaic device of the present invention.

### DETAILED DESCRIPTION

Thin film photovoltaic devices of the present invention include a poly(vinyl butyral) layer formulated according to the description herein, which provides excellent adhesion, resistivity, sealing, processability, and durability to the photovoltaic device.

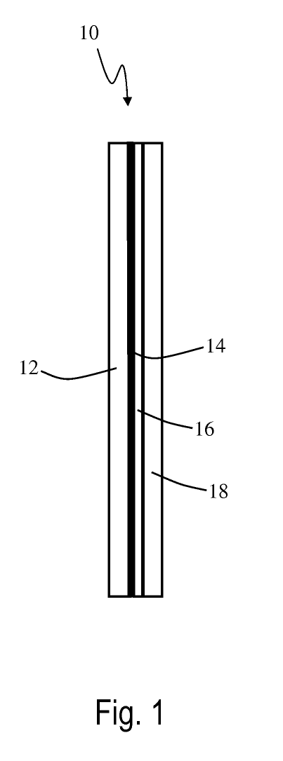

One embodiment of a thin film photovoltaic module of the present invention is shown in FIG. 1 generally at 10. As shown in the FIGURE, a photovoltaic device 14 is formed on a base substrate 12, which can be, for example, glass or plastic. A protective substrate 18 is bound to the photovoltaic device 14 with a poly(vinyl butyral) layer 16.

### Base Substrate

Base substrates of the present invention, which are shown as element 12 in FIG. 1, can be any suitable substrate onto which the photovoltaic devices of the present invention can be formed. Examples include, but are not limited to, glass, and rigid plastic glazing materials which yield “rigid” thin film modules, and thin plastic films such as poly(ethylene terephthalate), polyimides, fluoropolymers, and the like, which yield “flexible” thin film modules. It is generally preferred that the base substrate allow transmission of most of the incident radiation in the 350 to 1,200 nanometer range, but those of skill in the art will recognize that variations are possible, including variations in which light enters the photovoltaic device through the protective substrate.

### Thin Film Photovoltaic Device

Thin film photovoltaic devices of the present invention, which are shown as element 14 in FIG. 1, are formed directly on the base substrate. Typical device fabrication involves the deposition of a first conductive layer, etching of the first conductive layer, deposition and etching of semiconductive layers, deposition of a second conductive layer, etching of the second conductive layer, and application of bus conductors and protective layers, depending on the application. An electrically insulative layer can optionally be formed on the base substrate between the first conductive layer and the base substrate. This optional layer can be, for example, a silicon layer.

It will be recognized by those of skill in the are that the foregoing description of device fabrication is but one known method and is but one embodiment of the present invention. Many other types of thin film photovoltaic devices are within the scope of the present invention. Examples of formation methods and devices include those described in U.S. Patent documents 2003/0180983, U.S. Pat. Nos. 7,074,641, 6,455,347, 6,500,690, 2006/0005874, 2007/0235073, U.S. Pat. No. 7,271,333, and 2002/0034645, the relevant fabrication and device portions of which are incorporated herein in their entirety.

The various components of the thin film photovoltaic device can be formed through any suitable method. In various embodiments chemical vapor deposition (CVD), physical vapor deposition (PVD), and/or sputtering can be used.

The two conductive layers described above serve as electrodes to carry the current generated by the interposed semiconductor material. One of the electrodes typically is transparent to permit solar radiation to reach the semiconductor material. Of course, both conductors can be transparent, or one of the conductors can be reflective, resulting in the reflection of light that has passed through the semiconductor material back into the semiconductor material. Conductive layers can comprise any suitable conductive oxide material, such as tin oxide or zinc oxide, or, if transparency is not critical, such as for “back” electrodes, metal or metal alloy layers, such as those comprising aluminum or silver, can be used. In other embodiments, a metal oxide layer can be combined with the metal layer to form an electrode, and the metal oxide layer can be doped with boron or aluminum and deposited using low-pressure chemical vapor deposition. The conductive layers can be, for example, from 0.1 to 10 micrometers in thickness.

The photovoltaic region of the thin film photovoltaic device can comprise, for example, hydrogenated amorphous silicon in a conventional PIN or PN structure. The silicon can be typically up to about 500 nanometers in thickness, typically comprising a p-layer having a thickness of 3 to 25 nanometers, an i-layer of 20 to 450 nanometers, and an n-layer of 20 to 40 nanometers. Deposition can be by glow discharge in silane or a mixture of silane and hydrogen, as described, for example, in U.S. Pat. No. 4,064,521.

Alternatively, the semiconductor material may be micromorphous silicon, cadmium telluride (CdTe or CdS/CdTe), copper indium diselenide, (CuInSe₂, or “CIS”, or CdS/CuInSe₂), copper indium gallium selenide (CuInGaSe₂, or “CIGS”), or other photovoltaically active materials. Photovoltaic devices of this invention can have additional semiconductor layers, or combinations of the foregoing semiconductor types, and can be a tandem, triple-junction, or heterojunction structure.

Etching of the layers to form the individual components of the device can be performed using any conventional semiconductor fabrication technique, including, but not limited to, silkscreening with resist masks, etching with positive or negative photoresists, mechanical scribing, electrical discharge scribing, chemical etching, or laser etching. Etching of the various layers will result, typically, in the formation of individual photocells within the device. Those photocells can be electrically connected to each other using bus bars that are inserted or formed at any suitable stage of the fabrication process.

A protective layer can optionally be formed over the photocells prior to assembly with the poly(vinyl butyral) layer and the protective substrate. The protective layer can be, for example, sputtered aluminum.

The electrically interconnected photocells formed from the optional insulative layer, the conductive layers, the semiconductor layers, and the optional protective layer form the photovoltaic device of the present invention.

### Poly(Vinyl Butyral) Layer

The thin film photovoltaic modules of the present invention utilize a layer of poly(vinyl butyral), optionally comprising an epoxy, as a laminating adhesive that is used to seal the photovoltaic device to a protective substrate, thereby forming the photovoltaic module of the present invention.

Thin film photovoltaic devices are inherently difficult to laminate because of the presence of bus bars within the laminate. These bus bars are force concentrators that cause premature sealing during lamination, significantly reducing the deairing quality. Further, bus bars typically present step changes in thickness, which the poly(vinyl butyral) must flow into during the lamination step.

Poly(vinyl butyral) layers of the present invention can comprise poly(vinyl butyral) resins having an average molecular weight in the range of 70,000 to 150,000 Daltons, or 80,000 to 120,000 Daltons as shown in the table.

Values for other components of thin film photovoltaic poly(vinyl butyral) layers of the present invention can also be found in the table:

| Variable | Units | Range | Preferred Range |
|---|---|---|---|
| MW | Daltons | 70,000-150,000 | 80,000 to 120,000 |
| % OH (residual | % | 10-22 | 15-19 |
| hydroxyl) | | | |
| Plasticizer | phr | 0-40 | 10-38 |
| magnesium di-2- | titer | 0-20 | 5-10 |
| ethyl butyrate | | | |
| (RSS4) | | | |
| KOAC | titer | 0-20 | 0-5 |
| Epoxy | phr | 0-5 | 0-2 |
| Tinuvin ® | phr | 0.1-0.5 | 0.2-0.4 |
| Moisture | % | 0.05-0.6 | 0.20-0.45 |

The poly(vinyl butyral) layers of the present invention include low molecular weight epoxy additives. Any suitable epoxy agent can be used with the present invention, as are known in the art (see, for example, U.S. Pat. Nos. 5,529,848 and 5,529,849).

In various embodiments, epoxy compositions found usable as hereinafter described are selected from (a) epoxy resins comprising mainly the monomeric diglycidyl ether of bisphenol-A; (b) epoxy resins comprising mainly the monomeric diglycidyl ether of bisphenol-F; (c) epoxy resins comprising mainly the hydrogenated diglycidyl ether of bisphenol-A; (d) polyepoxidized phenol novolacs; (e) diepoxides of polyglycols, alternatively known as an epoxy terminated polyether; and (f) a mixture of any of the foregoing epoxy resins of (a) through (e) (see the Encyclopedia of Polymer Science and Technology, Volume 6, 1967, Interscience Publishers, N.Y., pages 209-271).

A suitable commercially available diglycidyl ether of bisphenol-A of class (a) is DER 331 from Dow Chemical Company. A diglycidyl ether of bisphenol-F epoxy of class (b) is EPON Resin DPL-862 and a hydrogenated diglycidyl ether of bisphenol-A epoxy of class (c) is EPONEX Resin 1510, both of which are available from Shell Chemical Company. A polyepoxidized phenol formaldehyde novolac of class (d) is available from Dow Chemical as DEN 431.

In a preferred embodiment, a diepoxide of poly(oxypropylene) glycol of class (e) is used and is available from Dow Chemical as DER 732.

Further examples of suitable epoxy agents include 3,4-epoxycyclohexane carboxylate compositions of the type described in U.S. Pat. No. 3,723,320. Also useful are diepoxides such as those disclosed in U.S. Pat. No. 4,206,067 that contain two linked cyclohexane groups to each of which is fused an epoxide group. Such diepoxide compounds correspond to Formula I:

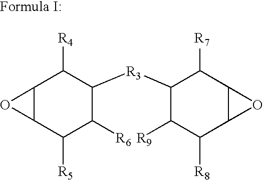

wherein R₃ is an organic group containing 1 to 10 carbon atoms, from 0 to 6 oxygen atoms, and from 0 to 6 nitrogen atoms, and R₄ through R₉ are independently selected from among hydrogen and aliphatic groups containing 1 to 5 carbon atoms. Exemplary diepoxides include 3,4-epoxycyclohexylmethyl-3,4-epoxycyclohexane, bis (3,4-epoxy-6-methylcyclohexylmethyl adipate), and 2-(3,4-epoxycyclohexyl)-5,5-spiro(3,4-epoxy)cyclohexane-m-dioxane.

A further useful epoxy is 2-ethylhexyl glycidyl ether (available from Resolution Products, Houston Tex., as Heloxy Modifier 116).

Further useful epoxies include diepoxides of poly(oxypropylene) glycol, 2-ethylhexyl glycidyl ether, and diepoxide products of epichlorohydrin and polypropylene glycol.

Mixtures of epoxy agents can also be used.

Epoxy agents can be incorporated into poly(vinyl butyral) layers in any suitable amount. In various embodiments, epoxy agents are incorporated as shown in the table. These amounts can be applied to any of the individual epoxy agents listed above, and in particular those shown in Formula I, and to the total amount of mixtures of the epoxy agents described herein.

In addition to the selection of the molecular weight of the poly(vinyl butyral) resin used and the epoxy agent used, a further parameter is the volume resistivity of the polymer layer, as this has a direct impact on the current leakage and efficiency of the photovoltaic module.

Conventional poly(vinyl butyral) interlayers have volume resistivities of approximately 10¹² Ω-cm at standard moisture levels. At the edges of the modules where the polymer layer can be exposed to the environment, however, volume resistivities can drop to 10¹¹ Ω-cm or lower, depending on environmental conditions.

The polymer layers of the current invention preferably maintain a volume resistivity of at least 5×10¹¹ Ω-cm.

Adhesion control agents (ACAs) of the present invention include those disclosed in U.S. Pat. No. 5,728,472. Additionally, residual sodium acetate and/or potassium acetate can be adjusted by varying the amount of the associated hydroxide used in acid neutralization. In various embodiments, polymer layers of the present invention comprise, in addition to sodium acetate and/or potassium acetate, magnesium bis(2-ethyl butyrate)(chemical abstracts number 79992-76-0). The magnesium salt can be included in an amount effective to control adhesion of the polymer layer, as shown in the table.

As used herein, “titer” can be determined for sodium acetate and potassium acetate (as used herein, the “total alkaline titer”) and magnesium salts in a sheet sample using the following method:

In order to determine the amount of resin in each sheet sample that is weighed, the following equation is used, where X is defined as the pounds per hundred pounds of resin including plasticizer and any other additives to the resin in the original sheet sample preparation.

$$Grams of resin in sheet sample = \frac{Grams sheet sample}{( 100 + X ) / 100}$$

Approximately 5 g of resin in the sheet sample is the target mass used to estimate the amount of sheet sample to start with, with the calculated mass of resin in the sheet sample used for each titer determination. All titrations should be completed in the same day.

The sheet sample is dissolved into 250 mls of methanol in a beaker. It may take up to 8 hours for the sheet sample to be completely dissolved. A blank with just methanol is also prepared in a beaker. The sample and blank are each titrated with 0.00500 normal HCl using an automated pH titrator programmed to stop at a pH of 2.5. The amount of HCl added to each the sample and the blank to obtain a pH of 4.2 is recorded. The HCl titer is determined according to the following:

$$HC 1 Titer [ mls 0.01 N HC 1 / 100 g resin ] = \frac{50 \times ( \begin{matrix}mls of HC 1 for sample - \\ mls of HC 1 for blank\end{matrix} )}{Calculated grams of resin}$$

To determine magnesium salt titer, the following procedure is used:

12 to 15 mls of pH 10.00 Buffer solution, prepared from 54 grams of ammonium chloride and 350. mls of ammonium hydroxide diluted to one liter with methanol, and 12 to 15 mls of Erichrome Black T indicator are added to the blank and each sheet sample, all of which have already been titrated with HCl, as described above. The titrant is then changed to a 0.000298 g/ml EDTA solution prepared from 0.3263 g tetrasodium ethylenediaminetetraacetate dihydrate, 5 ml water, diluted to one liter with methanol. The EDTA titration is measured by light transmittance at 596 nm. The % transmittance is first adjusted to 100% in the sample or blank before the titration is started while the solution is a bright magenta-pink color. When transmittance at 596 nm becomes constant, the EDTA titration is complete, and the solution will be a deep indigo color. The volume of EDTA titrated to achieve the indigo blue end point is recorded for the blank and each sheet sample. Magnesium salt titer is determined according to the following:

$$Magnesium Salt Titer [ as 1 \times {10}^{- 7} mole of magnesium salt per gram resin ] = \frac{\begin{matrix}0.000298 g / ml EDTA \times \\ ( \begin{matrix}mls of EDTA for sample - \\ mls of EDTA for blank\end{matrix} )\end{matrix}}{\begin{matrix}\begin{matrix}( grams of resin in sheet sample ) \times \\ 380.2 g / mole EDTA \times \end{matrix} \\ 0.0000001\end{matrix}}$$

From this result, total alkaline titer, as 1×10⁻⁷ mole of acetate salt per gram resin, can be calculated according to the following:

Total Alkaline Titer=HCl titer of sheet−(2× Total Magnesium Salt Titer)

The portion of the total alkalinity titer attributable to either sodium acetate or potassium acetate can be determined by first determining the total alkaline titer, as described above. After determining total alkaline titer, destructive analysis on the polymer sheet can be performed by Inductively Coupled Plasma Emission Spectroscopy (ICP) resulting in a ppm concentration for potassium and a ppm concentration for sodium.

The alkaline titer attributable to sodium acetate is defined herein as the total alkaline titer multiplied by the ratio [ppm sodium/(ppm sodium+ppm potassium)].

The alkaline titer attributable to potassium acetate is defined herein as the total alkaline titer multiplied by the ratio [ppm potassium/(ppm sodium+ppm potassium)].

Poly(vinyl butyral) can be produced by known acetalization processes that involve reacting poly(vinyl alcohol) with butyraldehyde in the presence of an acid catalyst, followed by neutralization of the catalyst, separation, stabilization, and drying of the resin.

As used herein, “resin” refers to the poly(vinyl butyral) component that is removed from the mixture that results from the acid catalysis and subsequent neutralization of the polymeric precursors. Resin will generally have other components in addition to the poly(vinyl butyral), such as acetates, salts, and alcohols.

Details of suitable processes for making poly(vinyl butyral) resin are known to those skilled in the art (see, for example, U.S. Pat. Nos. 2,282,057 and 2,282,026). In one embodiment, the solvent method described in Vinyl Acetal Polymers, in Encyclopedia of Polymer Science & Technology, 3^{rd} edition, Volume 8, pages 381-399, by B. E. Wade (2003) can be used. In another embodiment, the aqueous method described therein can be used. Poly(vinyl butyral) is commercially available in various forms from, for example, Solutia Inc., St. Louis, Mo. as Butvar™ resin.

As used herein, the term “molecular weight” means the weight average molecular weight. In addition to the ranges provided in the table, poly(vinyl butyral) layers of the present invention can have molecular weights of 120,000-150,000 Daltons, 100,000-120,000 Daltons, 70,000-120,000 Daltons, or 70,000-120,000 Daltons.

Any suitable plasticizers can be added to the poly(vinyl butyral) resins of the present invention in order to form the poly(vinyl butyral) layers. Plasticizers used in the poly(vinyl butyral) layers of the present invention can include esters of a polybasic acid or a polyhydric alcohol, among others. Suitable plasticizers include, for example, triethylene glycol di-(2-ethylbutyrate), triethylene glycol di-(2-ethylhexanoate), triethylene glycol diheptanoate, tetraethylene glycol diheptanoate, dihexyl adipate, dioctyl adipate, hexyl cyclohexyladipate, mixtures of heptyl and nonyl adipates, diisononyl adipate, heptylnonyl adipate, dibutyl sebacate, polymeric plasticizers such as the oil-modified sebacic alkyds, mixtures of phosphates and adipates such as those disclosed in U.S. Pat. No. 3,841,890 and adipates such as those disclosed in U.S. Pat. No. 4,144,217, and mixtures and combinations of the foregoing. Other plasticizers that can be used are mixed adipates made from C₄ to C₉ alkyl alcohols and cyclo C₄ to C₁₀ alcohols, as disclosed in U.S. Pat. No. 5,013,779, and C₆ to C₈ adipate esters, such as hexyl adipate. In preferred embodiments, the plasticizer is triethylene glycol di-(2-ethylhexanoate). In addition to the amounts of plasticizer given in the table, plasticizer can also be included in the amount of 25-35 phr, 15-25 phr, 5-15 phr, or 0-5 phr.

In some embodiments, the plasticizer has a hydrocarbon segment of fewer than 20, fewer than 15, fewer than 12, or fewer than 10 carbon atoms.

Additives may be incorporated into the poly(vinyl butyral) layer to enhance its performance in a final product. Such additives include, but are not limited to, plasticizers, dyes, pigments, stabilizers (e.g., ultraviolet stabilizers), antioxidants, flame retardants, other IR absorbers, UV absorbers, anti-block agents, combinations of the foregoing additives, and the like, as are known in the art.

One exemplary method of forming a poly(vinyl butyral) layer comprises extruding molten poly(vinyl butyral) comprising resin, plasticizer, and additives, and then forcing the melt through a sheet die (for example, a die having an opening that is substantially greater in one dimension than in a perpendicular dimension). Another exemplary method of forming a poly(vinyl butyral) layer comprises casting a melt from a die onto a roller, solidifying the melt, and subsequently removing the solidified melt as a sheet.

As used herein, “melt” refers to a mixture of resin with a plasticizer and, optionally, other additives. In either embodiment, the surface texture at either or both sides of the layer may be controlled by adjusting the surfaces of the die opening or by providing texture at the roller surface. Other techniques for controlling the layer texture include varying parameters of the materials (for example, the water content of the resin and/or the plasticizer, the melt temperature, molecular weight distribution of the poly(vinyl butyral), or combinations of the foregoing parameters). Furthermore, the layer can be configured to include spaced projections that define a temporary surface irregularity to facilitate the deairing of the layer during lamination processes after which the elevated temperatures and pressures of the laminating process cause the projections to melt into the layer, thereby resulting in a smooth finish.

As used herein, residual hydroxyl content (as vinyl hydroxyl content or poly(vinyl alcohol) (PVOH) content) refers to the amount of hydroxyl groups remaining as side groups on the polymer chains after processing is complete. For example, poly(vinyl butyral) can be manufactured by hydrolyzing poly(vinyl acetate) to poly(vinyl alcohol), and then reacting the poly(vinyl alcohol) with butyraldehyde to form poly(vinyl butyral). In the process of hydrolyzing the poly(vinyl acetate), typically not all of the acetate side groups are converted to hydroxyl groups. Further, reaction with butyraldehyde typically will not result in all hydroxyl groups being converted to acetal groups. Consequently, in any finished poly(vinyl butyral), there will typically be residual acetate groups (as vinyl acetate groups) and residual hydroxyl groups (as vinyl hydroxyl groups) as side groups on the polymer chain. As used herein, residual hydroxyl content is measured on a weight percent basis per ASTM 1396. In addition to the values provided in the table, poly(vinyl butyral) of the present invention can have a residual hydroxyl content of 10-15 or 15-17 weight percent.

In various embodiments of the present invention, the following specific combination of components are used:

110,000-130,000 Daltons poly(vinyl butyral), 8-12 phr triethylene glycol di-(2-ethylhexanoate), 17-21% residual hydroxyl, 8-12 titer magnesium di-2-ethyl butyrate loading, 4.2×10¹⁵+/−10% bulk resistivity.

40,000-60,000 Daltons poly(vinyl butyral), 8-12 phr triethylene glycol di-(2-ethylhexanoate), 17-21% residual hydroxyl, 8-12 titer magnesium di-2-ethyl butyrate loading, 2.8×10¹⁵+/−10% bulk resistivity.

110,000-130,000 Daltons poly(vinyl butyral), 18-22 phr triethylene glycol di-(2-ethylhexanoate), 17-21% residual hydroxyl, 8-12 titer magnesium di-2-ethyl butyrate loading, and a 2.6×10¹⁴+/−10% bulk resistivity.

140,000-150,000 Daltons poly(vinyl butyral), 32-40 phr triethylene glycol di-(2-ethylhexanoate), 17-21% residual hydroxyl, 8-12 titer magnesium di-2-ethyl butyrate loading, 1.8-2.2 phr epoxy DER™-732 loading, 1×10¹²+/−10% bulk resistivity.

110,000-130,000 Daltons poly(vinyl butyral), 30-38 phr triethylene glycol di-(2-ethylhexanoate), 18.7% residual hydroxyl, 8-12 titer magnesium di-2-ethyl butyrate loading, 8.0×10¹²+/−10% bulk resistivity.

140,000-150,000 Daltons poly(vinyl butyral), 27-35 phr triethylene glycol di-(2-ethylhexanoate), 14-18% residual hydroxyl, 8-12 titer magnesium di-2-ethyl butyrate loading, 3.5×10¹³+/−10% bulk resistivity.

210,000-230,000 Daltons poly(vinyl butyral), 20-28 phr triethylene glycol di-(2-ethylhexanoate), 9-13% residual hydroxyl, 8-12 titer magnesium di-2-ethyl butyrate loading, 2.7×10¹⁴+/−10% bulk resistivity.

40,000-60,000 Daltons poly(vinyl butyral), 16-24 phr triethylene glycol di-(2-ethylhexanoate), 17-21% residual hydroxyl, 8-12 titer magnesium di-2-ethyl butyrate loading, 2.8×10¹⁵+/−10% bulk resistivity.

40,000-60,000 Daltons poly(vinyl butyral), 21-29 phr triethylene glycol di-(2-ethylhexanoate), 17-21% residual hydroxyl, 8-12 titer magnesium di-2-ethyl butyrate loading, 1.5×10¹⁴+/−10% bulk resistivity.

### Protective Substrate

Protective substrates of the present invention, which are shown as element 18 in FIG. 1, can be any suitable substrate onto which the photovoltaic devices of the present invention can be formed. Examples include, but are not limited to, glass, rigid plastic, and thin plastic films such as poly(ethylene terephthalate), polyimides, fluoropolymers, and the like. It is generally preferred that the protective substrate allow transmission of most of the incident radiation in the 350 to 1,200 nanometer range, but those of skill in the art will recognize that variations are possible, including variations in which all of the light entering the photovoltaic device enters through the base substrate. In these embodiments, the protective substrate does not need to be transparent, or mostly so, and can be, for example, a reflective film that prevents light from exiting the photovoltaic module through the protective substrate.

### Assembly

Final assembly of thin film photovoltaic modules of the present invention involves disposing a poly(vinyl butyral) layer in contact with a thin film photovoltaic device, with bus bars, if applicable, that has been formed on a base substrate, disposing a protective substrate in contact with the poly(vinyl butyral) layer, and laminating the assembly to form the module.

The present invention includes a method of making a photovoltaic module, comprising the steps of providing a base substrate, forming a photovoltaic device thereon, and laminating the photovoltaic device to a protective substrate using a poly(vinyl butyral) layer of the present invention.

The present invention includes photovoltaic modules comprising polymer layers of the present invention.

### EXAMPLES

### Example 1

A poly(vinyl butyral) interlayer is formulated with a poly(vinyl butyral) resin having a molecular weight ranging from 110,000-130,000 Daltons, a plasticizer loading of 10 parts per hundred resin (phr) of triethylene glycol di-(2-ethylhexanoate), residual hydroxyl content of 18.7%, and a magnesium di-2-ethyl butyrate loading of 10 titer. The resulting sheet has a bulk resistivity of 4.2×10¹⁵ and a DF-135 of 31 microns. “DF135,” as used herein, is a test that correlates to autoclave flow and the ability of an interlayer to successfully laminate a complicated module with bus bars. DF135 is a measure of the depth a particular probe with a prescribed constant applied force sinks into an interlayer as the interlayer temperature is raised to 135° C.

### Example 2

A poly(vinyl butyral) interlayer is formulated with a poly(vinyl butyral) resin having a molecular weight ranging from 40,000-60,000 Daltons, a plasticizer loading of 10 phr of triethylene glycol di-(2-ethylhexanoate), residual hydroxyl content of 19.0%, and a magnesium di-2-ethyl butyrate loading of 10 titer. The resulting sheet has a bulk resistivity of 2.8×10¹⁵ and a DF135 of 407 microns.

### Example 3

A poly(vinyl butyral) interlayer is formulated with a polyvinyl butyral resin having a molecular weight ranging from 110,000-130,000 Daltons, a plasticizer loading of 20 phr of triethylene glycol di-(2-ethylhexanoate), a residual hydroxyl content of 18.7%, and a magnesium di-2-ethyl butyrate loading of 10 titer. The resulting sheet has a bulk resistivity of 2.6×10¹⁴ and a DF135 of 80 microns.

### Example 4

A poly(vinyl butyral) interlayer is formulated with a polyvinyl butyral resin having a molecular weight ranging from 140,000-150,000 Daltons, a plasticizer loading of 36 phr of triethylene glycol di-(2-ethylhexanoate), a residual hydroxyl content of 18.7%, and a magnesium di-2-ethyl butyrate loading of 10 titer, and epoxy DER™-732 loading of 2 phr. The resulting sheet has a bulk resistivity of 1×10¹² and a DF135 of 136 microns.

### Example 5

A poly(vinyl butyral) interlayer is formulated with a polyvinyl butyral resin having a molecular weight ranging from 110,000-130,000 Daltons, a plasticizer loading of 34 phr of triethylene glycol di-(2-ethylhexanoate), a residual hydroxyl content of 18.7%, and a magnesium di-2-ethyl butyrate loading of 10 titer. The resulting sheet has a bulk resistivity of 8.0×10¹² and a DF135 of 220 microns.

### Example 6

A poly(vinyl butyral) interlayer is formulated with a polyvinyl butyral resin having a molecular weight ranging from 140,000-150,000 Daltons, a plasticizer loading of 31 phr of triethylene glycol di-(2-ethylhexanoate), a residual hydroxyl content of 16.3%, and a magnesium di-2-ethyl butyrate loading of 10 titer. The resulting sheet has a bulk resistivity of 3.5×10¹³ and a DF135 of 277 microns. Equilibrium sheet moisture at 25% and 85% relative humidity are 0.33% and 1.89%, respectively.

### Example 7

A poly(vinyl butyral) interlayer is formulated with a polyvinyl butyral resin having a molecular weight ranging from 210,000-230,000 Daltons, a plasticizer loading of 24 phr of triethylene glycol di-(2-ethylhexanoate), a residual hydroxyl content of 10.7%, and a magnesium di-2-ethyl butyrate loading of 10 titer. The resulting sheet has a bulk resistivity of 2.7×10¹⁴ and a DF135 of 47 microns. Equilibrium sheet moisture at 25% and 85% relative humidity are 0.22% and 1.40%, respectively.

### Example 8

A poly(vinyl butyral) interlayer is formulated with a poly(vinyl butyral) resin having a molecular weight ranging from 40,000-60,000 Daltons, a plasticizer loading of 20 phr of triethylene glycol di-(2-ethylhexanoate), residual hydroxyl content of 19.0%, and a magnesium di-2-ethyl butyrate loading of 10 titer. The resulting sheet has a bulk resistivity of 2.8×10¹⁵ and a DF135 of 564 microns.

### Example 9

A poly(vinyl butyral) interlayer is formulated with a poly(vinyl butyral) resin having a molecular weight ranging from 40,000-60,000 Daltons, a plasticizer loading of 25 phr of triethylene glycol di-(2-ethylhexanoate), residual hydroxyl content of 19.0%, and a magnesium di-2-ethyl butyrate loading of 10 titer. The resulting sheet has a bulk resistivity of 1.5×10¹⁴ and a DF135 of 564 microns.

By virtue of the present invention, it is now possible to provide thin film photovoltaic modules having excellent physical stability.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

It will further be understood that any of the ranges, values, or characteristics given for any single component of the present invention can be used interchangeably with any ranges, values, or characteristics given for any of the other components of the invention, where compatible, to form an embodiment having defined values for each of the components, as given herein throughout. For example, the poly(vinyl butyral) epoxide ranges and plasticizer ranges can be combined to form many permutations that are within the scope of the present invention, but that would be exceedingly cumbersome to list.

Any FIGURE reference numbers given within the abstract or any claims are for illustrative purposes only and should not be construed to limit the claimed invention to any one particular embodiment shown in any FIGURE.

FIGURES are not drawn to scale unless otherwise indicated.

Each reference, including journal articles, patents, applications, and books, referred to herein is hereby incorporated by reference in its entirety.

We claim:

1. A thin film photovoltaic module, comprising:
a base substrate;
a thin film photovoltaic device disposed in contact with said first substrate;
a poly(vinyl butyral) layer disposed in contact with said photovoltaic device; and,
a protective substrate disposed in contact with said poly(vinyl butyral) layer, wherein said poly(vinyl butyral) layer comprises 25-35 parts per hundred resin plasticizer and has a molecular weight of 120,000-150,000 Daltons.

2. The module of claim 1, wherein said poly(vinyl butyral) layer comprises 15-25 parts per hundred resin plasticizer and has a molecular weight of 100,000-120,000 Daltons.

3. The module of claim 1, wherein said poly(vinyl butyral) layer comprises 5-15 parts per hundred resin plasticizer and has a molecular weight of 70,000-120,000 Daltons.

4. The module of claim 1, wherein said poly(vinyl butyral) layer comprises 0-5 parts per hundred resin plasticizer and has a molecular weight of 70,000-100,000 Daltons.

5. The module of claim 1, wherein said poly(vinyl butyral) layer further comprises an epoxy additive in the amount of 0-5 parts per hundred resin.

6. The module of claim 1, wherein said poly(vinyl butyral) layer further comprises an epoxy additive in the amount of 0-2 parts per hundred resin.

7. The module of claim 1, wherein said poly(vinyl butyral) layer has a residual hydroxyl content of 10-22.

8. The module of claim 1, wherein said poly(vinyl butyral) layer has a residual hydroxyl content of 15-17.

9. The module of claim 1, wherein said poly(vinyl butyral) layer has a residual hydroxyl content of 10-15.

10. The module of claim 1, wherein said poly(vinyl butyral) has 17-21% residual hydroxyl, 8-12 titer magnesium di-2-ethyl butyrate loading, and 4.2×10¹⁵+/−10% bulk resistivity.

11. A method of making a thin film photovoltaic module, comprising:
providing a base substrate;
forming a thin film photovoltaic device on said base substrate;
disposing a poly(vinyl butyral) layer in contact with said thin film photovoltaic device;
disposing a protective substrate in contact with said poly(vinyl butyral) layer; and,
laminating said base substrate, said photovoltaic device, said poly(vinyl butyral) layer, and said protective substrate to form said module, wherein said poly(vinyl butyral) layer comprises 25-35 parts per hundred resin plasticizer and has a molecular weight of 120,000-150,000 Daltons.

12. The method of claim 11, wherein said poly(vinyl butyral) layer comprises 15-25 parts per hundred resin plasticizer and has a molecular weight of 100,000-120,000 Daltons.

13. The method of claim 11, wherein said poly(vinyl butyral) layer comprises 5-15 parts per hundred resin plasticizer and has a molecular weight of 70,000-120,000 Daltons.

14. The method of claim 11, wherein said poly(vinyl butyral) layer comprises 0-5 parts per hundred resin plasticizer and has a molecular weight of 70,000-100,000 Daltons.

15. The method of claim 11, wherein said poly(vinyl butyral) layer further comprises an epoxy additive in the amount of 0-5 parts per hundred resin.

16. The method of claim 11, wherein said poly(vinyl butyral) layer further comprises an epoxy additive in the amount of 0-2 parts per hundred resin.

17. The method of claim 11, wherein said poly(vinyl butyral) layer has a residual hydroxyl content of 10-22 weight percent.

18. The method of claim 11, wherein said poly(vinyl butyral) layer has a residual hydroxyl content of 15-17.

19. The method of claim 11, wherein said poly(vinyl butyral) layer has a residual hydroxyl content of 10-15.

20. The method of claim 11, wherein said poly(vinyl butyral) has 17-21% residual hydroxyl, 8-12 titer magnesium di-2-ethyl butyrate loading, and 4.2×10¹⁵+/−10% bulk resistivity.
